(19) United States
(12) Patent Application Publication
(10) Pub. No.: US 2010/0162943 A1
(43) Pub. Date: Jul. 1, 2010

(54) SILICA GLASS CRUCIBLE AND METHOD OF PULLING SILICON SINGLE CYRSAL WITH SILICA GLASS CRUCIBLE

(75) Inventor: Hiroshi Kishi, Akita-shi (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: JAPAN SUPER QUARTZ CORPORATION, Akita-shi (JP)

(21) Appl. No.: 12/494,008

(22) Filed: Jun. 29, 2009

(30) Foreign Application Priority Data
Jun. 30, 2008 (JP) 2008-170278
Jun. 25, 2009 (JP) 2009-150729

(51) Int. Cl. C30B 15/10

(52) U.S. Cl. 117/13; 117/208

(57) ABSTRACT

In a silica glass crucible used for pulling a silicon crystal, a circumferential maximum tolerance of each of bubble content, wall thickness and transmission as measured over a full circumference of the crucible at a same height position is not more than 6%.

### BACKGROUND

1. Field of the Invention

The present invention relates to a silica glass crucible used for pulling a silicon single crystal as a semiconductor material, a silicon crystal as a solar battery material or the like, and more particularly to a silica glass crucible allowing the pulling of a silicon single crystal with a high crystallization rate and a method of pulling a silicon single crystal with the silica glass crucible.

2. Description of the Related Art

A silica glass crucible is used for pulling a silicon single crystal as a semiconductor material, a silicon crystal as a solar battery material or the like. For example, the silicon single crystal is mainly produced by a method in which a polycrystalline silicon lump charged in a silica glass crucible is melted by heating to form a silicon melt and a seed crystal is immersed in the silicon melt and pulled therefrom. The silicon crystal as a solar battery material is low in single-crystallinity as compared with a silicon single crystal, but is produced by the same pulling method.

The pulling of the silicon crystal is carried out by uniformly heating the silicon melt while rotating the silica glass crucible. In this case, if the bubble content and transmission in the circumferential direction of the crucible are non-uniform, brown rings produced in the inner surface of the crucible become unevenly distributed. Also, when the thickness of the crucible is non-uniform, the crucible form becomes faulty.

In the pulling of the silicon crystal, when the inner surface of the crucible is brought in contact with the silicon melt at a higher temperature for an expended period of time, a shallow surface layer inside the crucible is partially crystallized to generate a brown cristobalite in a ring shape (brown ring). As the uneven distribution of the brown rings or the faulty crucible form becomes significant, flaking portions in the inner surface of the crucible increase and the flaked fragments are incorporated into the silicon melt to reduce the crystallinity of the silicon crystal.

When the inner surface of the crucible is in contact with the silicon melt at a higher temperature for an extended period of time, SiO gas is generated by a reaction between the crucible inner surface and the silicon melt, whereby the silicon melt is oscillated to reduce the crystallinity of the silicon crystal.

In JP-A-2005-320241 is proposed a method of stably pulling a silicon crystal by restricting the number of brown rings within a certain range. In JP-A-2002-154894 is proposed that liquid-level oscillation of the silicon melt is prevented by using a silica glass crucible controlling an amount of SiO gas generated to not more than a certain level.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

It is, therefore, an object of the invention to solve the aforementioned problems on the reduction of the crystallinity due to brown rings or SiO gas generated in the pulling of the silicon crystal. According to the invention, there are provided standards of bubble content, thickness and transmission as measured over a circumference of a silica glass crucible at a given height position thereof for achieving a crystallinity of a silicon crystal above a given value, specifically acceptable ranges thereof in the silica glass crucible for obtaining a silicon crystal with a crystallinity of, for example, not less than 80%.

The invention is concerned with a silica glass crucible having the following construction:

(1) A silica glass crucible used for pulling a silicon crystal, characterized in that a circumferential maximum tolerance of each of bubble content, wall thickness and transmission as measured over a full circumference of the crucible at a same height position is not more than 6%.

(2) A silica glass crucible according to the item (1), wherein the circumferential maximum tolerance of each of the bubble content, wall thickness and transmission is not more than 3%.

(3) A silica glass crucible according to the item (1), wherein the circumferential maximum tolerance of each of the bubble content, wall thickness and transmission is not more than 1.5%.

(4) A method of pulling a silicon single crystal, comprising using a silica glass crucible as described in any one of the items (1) to (3).

The silica glass crucible according to the invention is a silica glass crucible used for pulling a silicon crystal in which a circumferential maximum tolerance of each of bubble content, wall thickness and transmission as measured over a full circumference of the crucible at a same height position is not more than 6%, so that a higher crystallinity can be attained without substantially causing the liquid-level oscillation of the silicon melt and the flaking of the crucible inner surface during the pulling of the silicon crystal.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 is a longitudinal sectional view of a silica glass crucible

### DETAILED DESCRIPTION

While illustrative embodiments have been illustrated and described, it will be appreciated that various changes can be made therein without departing from the spirit and scope of the invention.

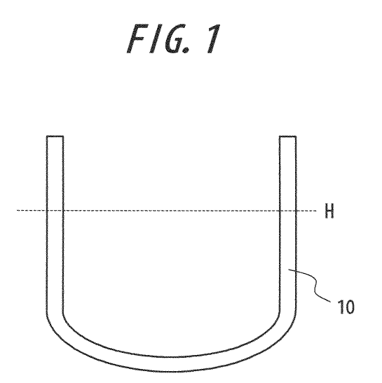

The silica glass crucible according to the invention is a silica glass crucible used for pulling a silicon crystal. In FIG. 1 is shown a schematically longitudinal sectional view of the silica glass crucible according to the invention. In the silica glass crucible 10 according to the invention, the circumferential maximum tolerance of each of bubble content, wall thickness and transmission at the same crucible height position H is not more than 6%, preferably not more than 3%, more preferably not more than 1.5%.

The term “circumferential maximum tolerance” used herein is a percentage of a value obtained by subtracting an average value of each of the bubble content, wall thickness and transmission as measured over the full circumference of the crucible at the same height position from a value most deviated therefrom. For example, when the average value is A and the value most deviated from the average value is B, the circumferential maximum tolerance X (%) is given by the following equation [1]:

Circumferential maximum tolerance X (%)=Absolute value of ((B−A)/A)×100 [1]

When the crucible is constituted with a two-layer structure of an outer layer made of natural quartz glass and an inner layer made of synthetic silica glass, the bubble content means a bubble content of the inner layer, concretely a bubble content of a transparent glass layer forming the inner layer of the crucible. Generally, in case of the silica glass crucible having a diameter of 32 inches, the transparent glass layer as an inner layer of the crucible corresponds to a layer portion having a thickness of about 0.5 to 10 mm from the inner surface of the crucible.

The wall thickness is a shortest distance of a section portion ranging from the inner surface to the outer surface of the crucible.

The transmission is a transmission of a section portion ranging from the outer surface to the inner surface of the crucible.

Moreover, the same height position H of the crucible may have a certain width required for measuring the bubble content, wall thickness and transmission.

The crystallinity of not less than 80% can be obtained in the pulling of a silicon crystal by controlling the circumferential uniformity of the silica glass crucible so that the circumferential maximum tolerance of each of the bubble content, wall thickness and transmission at the same height position of the crucible is not more than 6%.

On the other hand, if the circumferential maximum tolerance of either of the bubble content, wall thickness and transmission of the silica glass crucible exceeds 6%, the crystallinity significantly lowers. Incidentally, the flaking tends to be caused on the inner surface of the crucible when the circumferential maximum tolerances of the bubble content and wall thickness exceed 6%, while the liquid-level oscillation of the silicon melt tends to be caused when the circumferential maximum tolerance of the transmission exceeds 6%. In any cases, the crystallinity significantly lowers.

The silica glass crucible of the invention can be produced by a method of producing a crucible by depositing silica or quartz powder on an inner surface of a rotating crucible-like mold and heating the silica or quartz powder layer at a higher temperature to be vitrified under the rotation of the mold, wherein a dial gauge is put on the inner surface of the mold and a lateral oscillating level of the inner surface is controlled to not more than 0.1% of an inner diameter of the mold.

The invention will be described concretely with reference to examples and comparative examples. Moreover, the bubble content, wall thickness and transmission are measured by the following methods. Also, the crystallinity is determined by a ratio of weight of a straight base portion of a pulled crystal ingot to weight of a starting material charged.

The height position H of the crucible to be measured is set to a height at a middle position between a bottom position of the crucible and an upper end position of a sidewall portion of the crucible when an opening of the crucible is in an upward direction (in case of a 28 inch crucible as an example, the height position H is 250 mm from the bottom position of the crucible).

The bubble content is determined by an area of bubbles occupied per unit area in a transparent layer as an inner layer of the crucible (a portion having a thickness of 1 mm from the inner surface of the crucible).

The wall thickness is determined by measuring wall thickness ranging from the outer surface to the inner surface of the crucible at the measuring height position and calculating an average value thereof.

The transmission is calculated by the following equation:

Transmission (%)=(W1/W0)×100

when an infrared ray quantity at a state of disposing the crucible between an infrared ray irradiation apparatus and an infrared ray measuring instrument is W1 and an infrared ray quantity at a state of disposing no crucible between an infrared ray irradiation apparatus and an infrared ray measuring instrument is W0.

### Examples 1 to 3

A silica glass crucible according to the invention (inner diameter: 32 inches) is produced according to conditions shown in Table 1, and then a silicon crystal is pulled. The results are shown in Table 1.

### Comparative Examples 1 to 4

A silica glass crucible (inner diameter: 32 inches) is produced according to conditions shown in Table 1, and then a silicon crystal is pulled. The results are shown in Table 1.

TABLE 1

| | Circumferential maximum | | | | | |
|---|---|---|---|---|---|---|
| | tolerance (%) | | | Liquid- | Flaking | Crystal- |
| | Bubble | Wall | Trans- | level | of inner | linity |
| | content | thicknes | mission | oscillation | surface | (%) |
| Example 1 | 1.3 | 1.1 | 1.2 | None | None | 84 |
| Example 2 | 2.5 | 2.7 | 2.9 | None | None | 82 |
| Example 3 | 5.8 | 5.6 | 5.4 | None | None | 80 |
| Comparative | 6.9 | 1.8 | 1.5 | None | Existent | 39 |
| Example 1 | | | | | | |
| Comparative | 2.2 | 7.2 | 2.8 | None | Existent | 36 |
| Example 2 | | | | | | |
| Comparative | 1.8 | 2.7 | 7.7 | Existent | None | 41 |
| Example 3 | | | | | | |
| Comparative | 7.2 | 8.2 | 7.6 | Existent | Existent | 30 |
| Example 4 | | | | | | |

As seen from Table 1, the crystallinity of not less than 80% is obtained without causing liquid-level oscillation of silicon melt and flaking the inner surface of the crucible in all of Examples 1 to 3. Moreover, the crystallinity is 80% in Example 3 wherein the circumferential maximum tolerance of each of the bubble content, wall thickness and transmission is more than 3% but not more than 6%, while the crystallinity is as high as 82% in Example 2 wherein the circumferential maximum tolerance is more than 1.5% but not more than 3%, and also the crystallinity is the highest of 84% in Example 1 wherein the circumferential maximum tolerance is not more than 1.5%. On the other hand, the crystallinity is not more than 41% in any of Comparative Examples 1 to 3, which is considerably lower than those of Examples 1 to 3. Particularly in Comparative Example 4 wherein the circumferential maximum tolerance of each of the bubble content, wall thickness and transmission exceeds 6%, the liquid-level oscillation of silicon melt and the flaking of the inner surface of the crucible are caused and the crystallinity is the lowest of 30%.

1. A silica glass crucible used for pulling a silicon crystal, characterized in that a circumferential maximum tolerance of each of bubble content, wall thickness and transmission as measured over a full circumference of the crucible at a same height position is not more than 6%.

2. A silica glass crucible according to claim 1, wherein the circumferential maximum tolerance of each of the bubble content, wall thickness and transmission is not more than 3%.

3. A silica glass crucible according to claim 1, wherein the circumferential maximum tolerance of each of the bubble content, wall thickness and transmission is not more than 1.5%.

4. A method of pulling a silicon single crystal, comprising using a silica glass crucible as claimed in claim 1.

5. A method of pulling a silicon single crystal, comprising using a silica glass crucible as claimed in claim 2.

6. A method of pulling a silicon single crystal, comprising using a silica glass crucible as claimed in claim 3.
